(19) United States
(12) Patent Application Publication
(10) Pub. No.: US 2020/0118720 A1
(43) Pub. Date: Apr. 16, 2020

(54) TUNABLE MULTI-SEGMENT THERMISTOR

(71) Applicant: TEXAS INSTRUMENTS INCORPORATED, Dallas, TX (US)

(72) Inventors: William David French, San Jose, CA (US); Erika Lynn Mazotti, San Martin, CA (US); Dok Won Lee, Mountain View, CA (US); Keith Ryan Green, Prosper, TX (US)

(21) Appl. No.: 16/597,100

(22) Filed: Oct. 9, 2019

Related U.S. Application Data
(60) Provisional application No. 62/744,257, filed on Oct. 11, 2018.

(51) Int. Cl. H01C 10/46; H01L 23/64; H01L 23/495

(52) U.S. Cl. CPC H01C 10/46; H01L 23/49503; H01L 23/647

(57) ABSTRACT

Various examples provide an electronic device that includes first and second rectangular resistor segments, each resistor segment having a doped resistive region formed in a semiconductor substrate. The first resistor segment has a first trim end and a first bridge end, and the second resistor segment has a second bridge end. The first bridge end is adjacent the second bridge end. A conductive interconnect line connects to the first bridge end and to the second bridge end. At least one connection terminal to the first resistor segment is located at the first trim end.

### CROSS REFERENCE TO RELATED APPLICATIONS

This application claims the benefit of Provisional Application Ser. No. 62/744,257 entitled “Tunable Multi-Segment Thermistor” filed Oct. 11, 2018, which is herein incorporated by reference in its entirety. This application is related to U.S. Patent Application No. ______, (Texas Instruments docket number TI-90155) entitled “Trimmable Silicon-Based Thermistor with Reduced Stress Dependence”, filed on even date herewith, which is herein incorporated by reference in its entirety.

### FIELD

This disclosure relates to the field of semiconductor devices, and more particularly, but not exclusively, to resistive devices, e.g. thermistors.

### BACKGROUND

Thermistors are used in a wide variety of applications, including electronics, battery systems, environmental control, petroleum exploration and medical monitoring. In a resistance value of a thermistor differs from a nominal design value due to, e.g. manufacturing variation. Thus some thermistor designs include a mechanism to adjust the resistance to more closely approach the design resistance value.

### SUMMARY

The inventors disclose various methods and devices that may be beneficially applied to manufacturing electronic devices including a thermistor (potentiometer), with improved die area utilization, lower manufacturing variability and smaller incremental trim resistance. While such embodiments may be expected to provide improvements in reliability of devices, no particular result is a requirement of the described invention(s) unless explicitly recited in a particular claim.

Various examples provide an electronic device that includes first and second rectangular resistor segments, each resistor segment having a doped resistive region formed in a semiconductor substrate. The first resistor segment has a first trim end and a first bridge end, and the second resistor segment has a second bridge end. The first bridge end is adjacent the second bridge end. A conductive interconnect line connects to the first bridge end and to the second bridge end. At least one connection terminal to the first resistor segment is located at the first trim end.

### BRIEF DESCRIPTION OF THE VIEWS OF THE DRAWINGS

FIG. 1 illustrates one implementation of a segmented resistor within the scope of the disclosure, e.g. having five segments;

FIG. 2 illustrates another implementation of a segmented resistor within the scope of the disclosure, e.g. having two segments;

FIG. 3 illustrates an embodiment of a segmented resistor having two segments, with a length and a width shown for reference, and three cut locations marked corresponding to FIGS. 4A, 4B and 4C;

FIGS. 4A-4C provides a various sectional views of the example of FIG. 3;

FIGS. 5 illustrates two groupings of contact lines having different fill densities;

FIG. 6 illustrates a single-segment resistor implementation;

FIG. 7 illustrates an example of a two-segment resistor implemented on a semiconductor die consistent with principles of the disclosure;

FIGS. 8A and 8B illustrate directions of carrier flow in a (100) silicon wafer in <110> directions (8A) and <100> directions (8B);

FIG. 9 illustrates an example of in-plane stress that may be placed on the semiconductor die of FIG. 7 by a device package;

FIG. 10 illustrates one embodiment of the connections to adjustment lines of a two-segment resistor consistent with the principles of the disclosure, wherein each adjustment line is connected to an individual connection pad;

FIG. 11 illustrates one embodiment of connections to the adjustment lines of a two-segment resistor consistent with the principles of the disclosure, wherein adjustment lines of each segment are connected to a corresponding single connection pad via fuses arranged in series;

FIG. 12 illustrates one embodiment of connections to the adjustment lines of a two-segment resistor consistent with the principles of the disclosure, wherein adjustment lines of each segment are connected to a corresponding single connection pad via fuses arranged in parallel;

FIG. 13 illustrates a method of forming an electronic device, such as segmented resistor of FIG. 3; and

FIGS. 14A-14F illustrate aspects of forming an electronic device or integrated circuit including a segmented resistor according to principles of the disclosure.

### DETAILED DESCRIPTION

The present disclosure is described with reference to the attached figures. The figures may not be drawn to scale and they are provided merely to illustrate the disclosure. Several aspects of the disclosure are described below with reference to example applications for illustration, in which like features correspond to like reference numbers. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events may be required to implement a methodology in accordance with the present disclosure.

Some thermistors use a diffused resistor body that has a positive temperature coefficient. (See, e.g. U.S. patent application Ser. No. 15/639,492, Texas Instruments docket number 78126, referred to hereinafter as “the '492 application’, incorporated by reference herein in its entirety.) One version of this diffused resistor body has an n-type doped region that includes a central body, and two end regions. The end regions each include evenly spaced connection lines that connect to the resistor body via a heavily doped region of the body. Selection of the appropriate connection lines to connect to the resistor body may provide the ability to trim the resistance to ±1% of a target value. But the single resistor body may not result in efficient use of device die area, and may also be sensitive to stress imposed by device packaging. Furthermore, the geometric constraints on length and width limit design flexibility of resistance adjust increment.

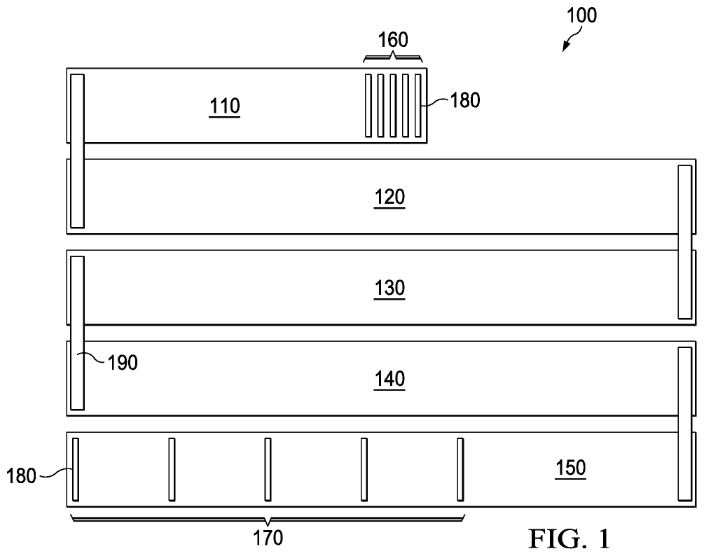

FIG. 1 illustrates an embodiment of a multi-segment diffused resistor 100 according to principles of the disclosure having five segments 110-150 formed in a semiconductor substrate. Segments 110 and 150 are referred to as “end segments”, while segments 120, 130 and 140 are referred to as “interior segments”. The segment 110 includes a head region 160, and the segment 150 includes a head region 170. Each of the head regions 160, 170 includes a number of connection lines 180. Each of the connection lines 180 may be regarded as connection terminal to the segment to which that connection line 180 is directly connected. The connection lines 180 in the head region 160 are spaced apart by a first distance, while those in the head region 170 are spaced apart by a second, greater distance. Each segment 110-150 is connected to a neighboring segment by a bridge line 190 that contacts corresponding segments near ends of the segments. The interior segments 120, 130, 140 are each connected to two neighboring segments, while the end segments 110, 150 are only connected to a single neighboring segment.

As described further below, each segment 110-150 includes a diffusion region of a first conductivity type, e.g. n-type, formed in the semiconductor substrate, e.g. Si, having a second conductivity type, e.g. p-type. Thus each segment may be regarded as a separate and distinct diffusion resistor. The lines 180, 190 may be a metal, e.g. Al or Cu, or may be a doped semiconductor, e.g. polysilicon. The lines 180, 190 are connected to the underlying segment by vias and/or contacts (not shown). The segments 110-150, lines 180, 190 and vias and/or contacts may be formed by processes that are conventional, or by one or more future-developed processes.

As a matter of terminology, a resistor segment may have a long axis and a short axis. In general the segment is rectangular, meaning the short axis is shorter than the long axis. As used herein in the context of a segment, “length” refers to the extent of the segment in the direction of the long axis, and “width” refers to the extent of the segment in the direction of the short axis. Length may be abbreviated as “L”, and width may be abbreviated as “W”. For a rectangular segment, L>W. In the particular case of a square segment, the long axis and the short axis are considered to be equal. The ratio of L/W may be referred to as an “aspect ratio” of the resistor segment. The resistance of a segment may be determined in part by its length and its width, and to a first order may be proportional to the aspect ratio. As discussed further below, a junction between the diffusion region and the substrate generally forms, and may increase the resistance of a segment by depleting charge carriers from a region of the segment near the junction. This effect is generally dependent on the doping level of the segment and/or substrate, and on the voltage difference between the segment and the substrate.

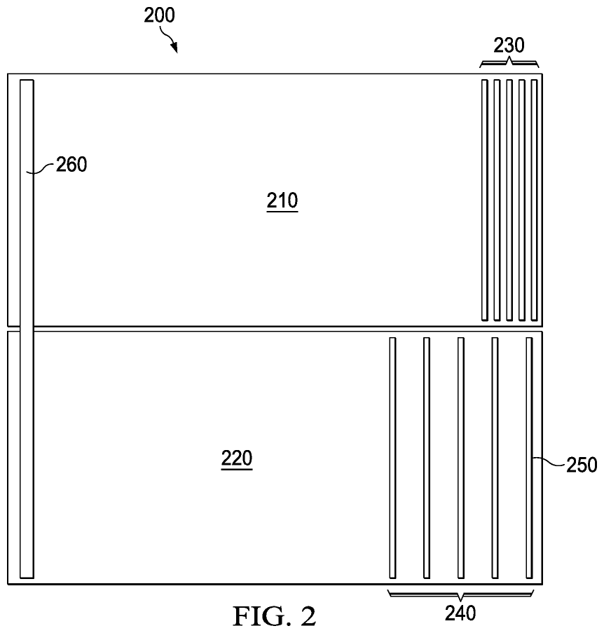

FIG. 2 illustrates another embodiment of a multi-segment resistor 200 according to principles of the disclosure. The resistor 200 includes two segments 210, 220, e.g. two end segments and no interior segments. The segment 210 includes a head region 230 and the segment 220 includes a head region 240. Each head region 230, 240 includes a number of connection lines 250, shown as five for example. Each of the connection lines 250 may be regarded as connection terminal to the segment to which that connection line 250 is directly connected. The connection lines 250 may also be referred to as “trim terminals”, as the resistance value of the resistor 200 may be trimmed by connection to appropriate ones of the connection lines 250. As illustrated, the connection terminals may preferably be configured as lines that span substantially the entire width of the segment. The segments 210, 220 are conductively connected by a bridge line 260 at ends opposite the head regions 230, 240. Accordingly, the end of each segment 210, 220 at which the trim terminals are located may be referred to as the “trim end”, and the end opposite the trim end may be referred to as the “bridge end”. An interior segment, such as the segment 130 (FIG. 1) has two bridge ends and no trim end. The segments 110-150 in FIG. 1 are longer and narrower than the segments 210, 220 in FIG. 2. A resistor design such as that of the resistor 100 may therefore be suitable for larger resistance values while a resistor design such as that of the resistor 200 may be suitable for smaller larger resistance values. For example, without implied limitation the resistor 100 may implement a 100 kΩ nominal resistance, and the resistor 200 may implement a 10 kΩ resistance. For simplicity, aspects of the resistor 200 will be described in detail below, with the understanding that the described principles may be applied to segmented resistors having more than two segments, such as the resistor 100.

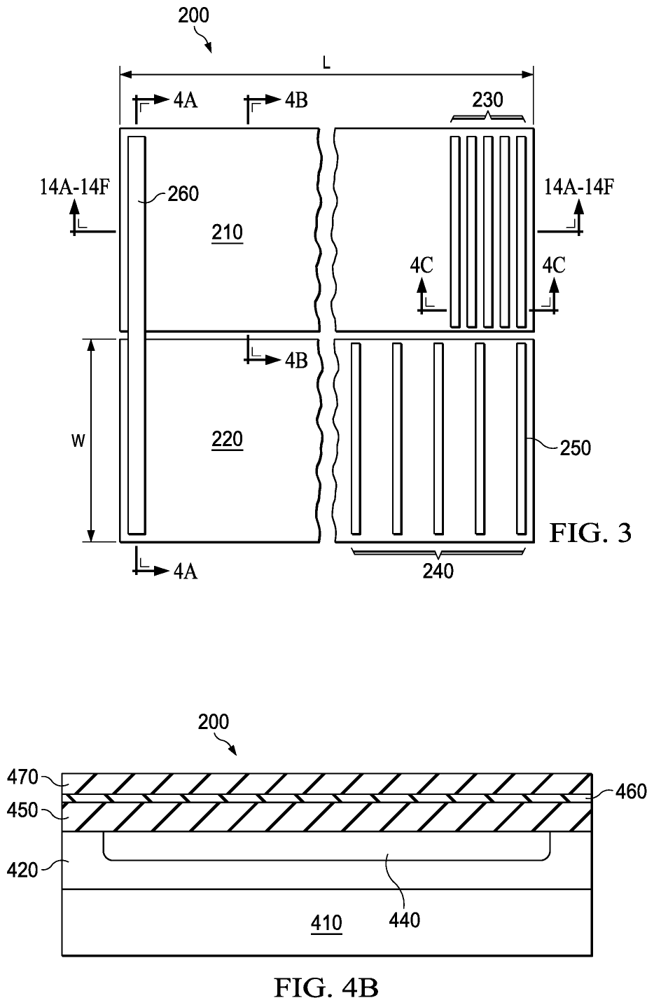

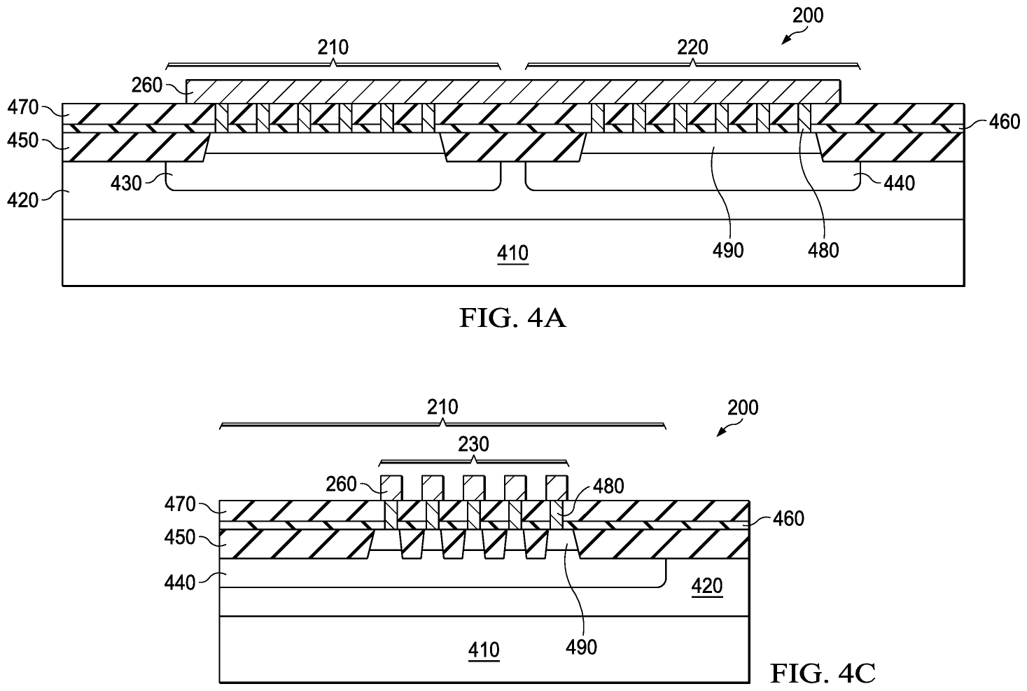

FIG. 3 illustrates the resistor 200 with length L and width W shown for reference, and three cut locations marked corresponding to FIGS. 4A, 4B and 4C. Referring to FIG. 4A, a cut through the long axis of the bridge line 260 is shown, and the illustration includes other structural features of the resistor 200. The resistor 200 is formed over a substrate 410, which in general is a semiconductor substrate doped to provide the second conductivity type, e.g. p-type. In a nonlimiting example the substrate 410 may be a lightly-doped p-type substrate. An epitaxial layer 420, also of the second conductivity type, may optionally be formed over the substrate 410, and further description assumes without implied limitation the presence of the epitaxial layer 420. Doped regions 430 and 440 are located within the epitaxial layer, and may be formed by a process sometimes used to form “deep” wells in semiconductor processing. The doped regions 430, 440 have the first conductivity type, e.g. n-type, and may be referred to as deep n-wells. An isolation layer 450, illustrated as including portions of shallow trench isolation (STI) structures, is located along a top surface of the epitaxial layer 420. In some examples, the isolation layer may be implemented by local oxidation of silicon (LOCOS). First and second dielectric layers 460, 470 are located over the epitaxial layer 420 surface. In various embodiments the first dielectric layer 460 includes silicon nitride, and the second dielectric layer 470 includes silicon dioxide. Embodiments are not limited to such dielectrics, and in come embodiments the first dielectric layer may be omitted. The bridge line 260 is located on the second dielectric layer 470. Vias 480 connect the bridge line 260 to heavily-doped regions 490, e.g. n+ regions, within the doped regions 430 and 440. In some embodiments the vias are formed by a process that may be used to form structures sometimes referred to as “contacts”, e.g. tungsten plugs. Thus the vias may also be referred to herein as contacts.

FIG. 4B illustrates a cut through the resistor 200 at a location between the ends of the segment 210. The isolation layer 450 is uninterrupted at this location, as are the dielectric layers 460 and 470.

FIG. 4C illustrates a cut through the head region 230. Each of five connection lines 250 is connected to the doped region 440 by corresponding vias 480 and n+regions 490. The connection lines 250 are conductively isolated above the substrate 410, but are conductively coupled through the doped region 440.

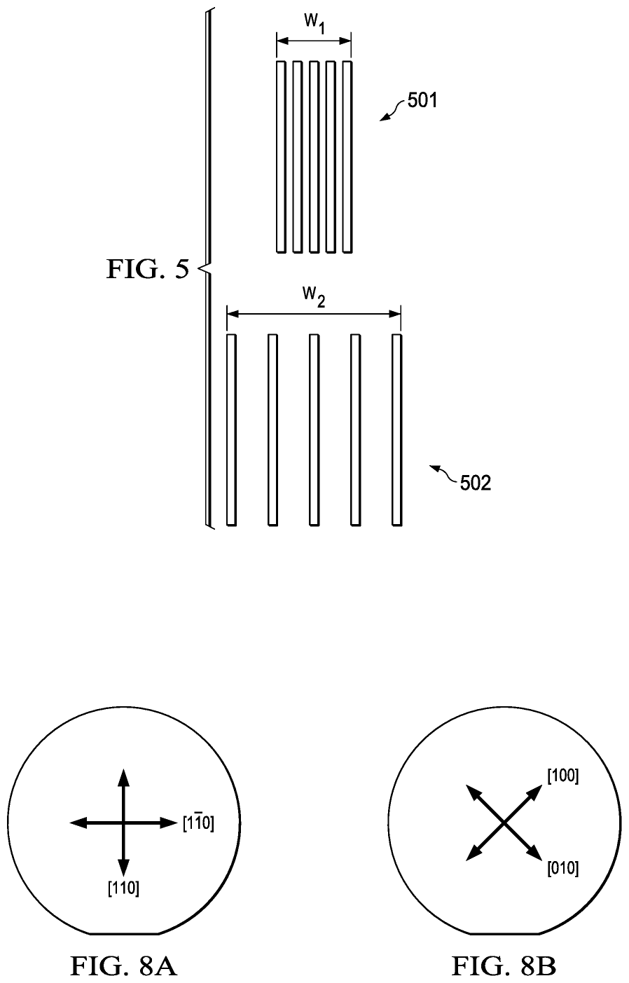

FIG. 5 illustrates two groups of connection lines that may be used to connect to a resistor body such as the doped region 430 or 440. Lines 501 fill a group width W₁, determined from the outside edge of the left-most line to the outside edge of the rightmost line. The lines are shown as being evenly spaced, but in other embodiments that lines may be unevenly spaced. The lines are further shown as having a same width, but in other embodiments that lines may have different widths. The set of lines 501 has a total group line width that is the sum of the widths of the individual lines. A fill density of the group of lines is defined as the ratio of the total group linewidth to the group width W₁. The fill density of the lines 501 is about 50%. Lines 502 fill a group width W₂. In this example, the total group linewidth is the same as that for the lines 501, but the spacing between the lines is greater. Thus the lines 502 have a fill density that is lower than the lines 501, e.g. about 20%.

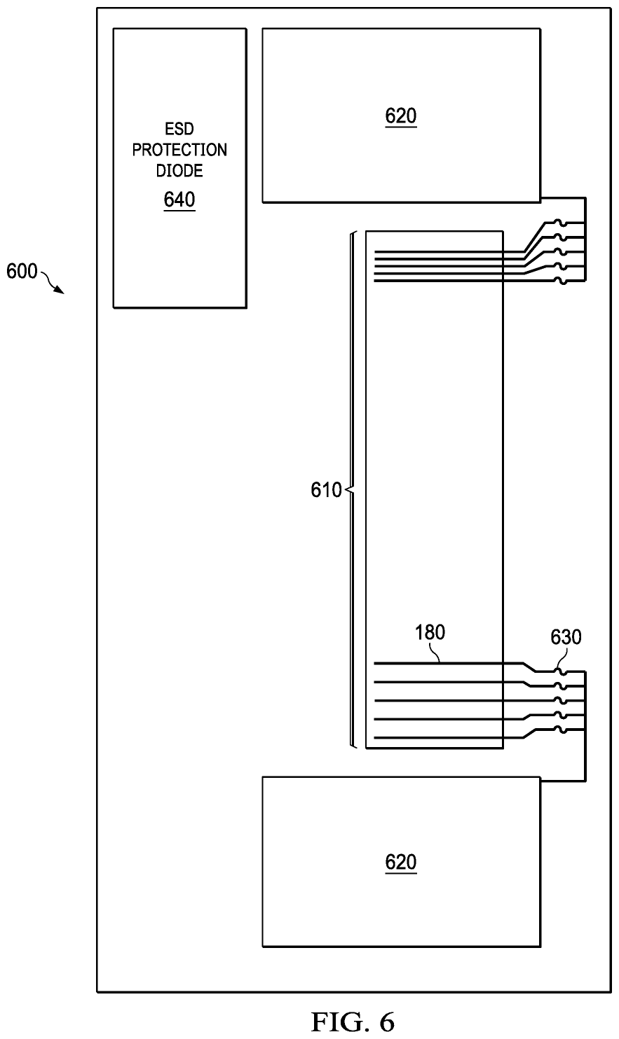

FIG. 6 illustrates a device 600 die that implements a resistor 610 using a single resistor body configured consistent with the design practice described in the '492 application. The resistor 610 is shown with relative length and width that provides a target resistance. An optional ESD (electrostatic discharge) protection diode 640 is located on the die to protect the resistor 610 from electrostatic discharge events. The ESD protection diode is typically connected to a neighboring connection pad 620 by way of an extension (not shown) of the metal layer from which the pad 620 is formed. The resistor 610 includes connection lines at each end of the resistor body. One set is relatively closely spaced, having a first fill density, and the other set is relatively widely spaced, having a second lower fill density. Each connection line is connected to a connection pad 620 via a corresponding fuse 630. The resistance provided by the device 600 may adjusted, or “trimmed” by selectively severing the connection of a subset of the connection lines to the connection pads, for example by opening, or “blowing”, a subset of the fuses 630. The trim increment is greater for the widely spaced connection lines, and smaller for the closely spaced connection lines. Thus the more widely spaced connection lines provide a coarse trim, and the more narrowly spaced connection lines provide a fine trim.

It can be seen that this die of the device 600 has a significant amount of unused area. This relatively inefficient use of the die area results in part from the geometrical constraints imposed by the length and width required to implement the target resistance. The inventors have determined that some of this unused area may be advantageously filled by using a segmented resistor according to various described embodiments. The multiple resistor segments may be wider than an implementation using a single resistor segment, addressing some of the constraints of the single-body resistor design.

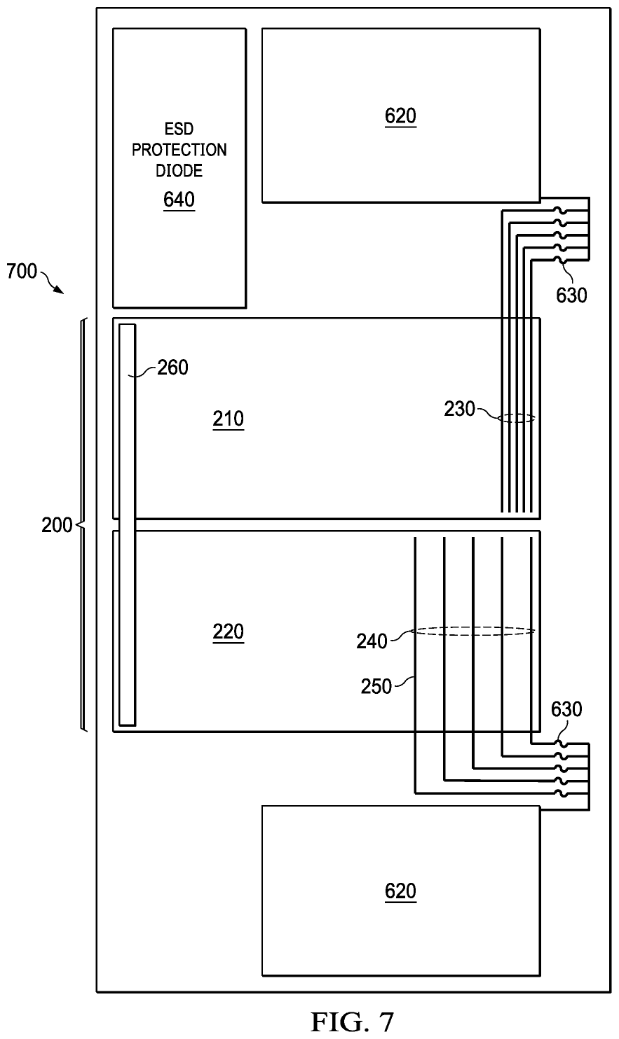

FIG. 7 illustrates a device 700 die that implements a multiple segment resistor, e.g. having two segments, according to principles of the present disclosure. The resistor 200 is used in a nonlimiting example. The connection lines 250, bridge line 260, connection pads 620 and fuses 630 may be implemented in an interconnect layer of the device 700, for example copper or aluminum. The connection pads 620 may be configured to be used as wire-bonding terminals (e.g. bond pads), such as by having a minimum side length of about 80 μm. The length and width of the segments 210, 220 are shown with relative values such that the resistor 200 provides about the same nominal target resistance as does the resistor 610. It is immediately apparent that unused area on the device 700 die is significantly less than that of the device 600. The greater utilization is due in part to implementing the target resistance with wider resistor segments that have a smaller aspect ratio than the resistor 610. The combined length of the segments 210, 220 is also greater than the length of the resistor 610, consistent with the proportionality of the resistance to the ratio of length to width. As was described for the device 600, the device 700 also provides fusible connections from each connection line to one of two connection pads by way of the fuses 630. In this case, however, fine trimming is provided only on the segment 210, and coarse trimming is provided only on the segment 220.

An optional feature, not shown, includes a scribe seal that circumscribes the device 700 on a device die. The scribe seal may be conductively connected to the connection pad 620. The scribe seal thus may act as a substrate contact, eliminating the need for a separate substrate contact on the device die.

The greater width, lower aspect ratio and total length of the segments 210 and 220 may beneficially improve consistency of resistance of instances of the device 700 formed on a single semiconductor wafer by reducing the effect of process nonuniformity on the resulting resistance of the devices 700. The greater width of the segments 210, 220 as compared to the resistor 610 may also provide advantageous process flexibility. It is generally desirable to obtain a trim increment that is as small as possible so that the completed resistor may be trimmed as close as possible to a target resistance, e.g. 10 kΩ. The wider resistor body segments of the resistor 200 as compared to the resistor 100 result in a smaller possible trim increment for the wider resistor body. One result of this smaller trim increment is a tighter distribution of resistances of a population of die formed on a single wafer after trimming. This aspect may result in greater process margin to achieve a desired resistance target after packaging, which as described below may affect the resistance due to piezo-resistive effects. While the aspect ratio of the resistor segments 210 and 220 is not limited to any particular value, it is expected that the benefits of the greater width will be apparent when the aspect ratio is as close to 1:1 as possible given other geometric constraints within the device die. Without implied limitation, in the example of the device 700, the aspect ratio of the resistor segments 210 and 220 is about 2:1, which may be considered in some implementations to be an upper limit of the aspect ratio.

The use of the segmented design as exemplified by the resistors 100 and 200 may provide a same resistance as the single-body design of the device 600, while providing various additional benefits. For example, the wider body may allow a smaller minimum trim code resistance, e.g. less than 50 Ω. Moreover, the greater total length of the multiple resistor bodies, relative to a single resistor body, may provide design flexibility regarding the number and spacing of the trim terminals, further enabling smaller adjustment increments. Another advantage of the wider body region may be a lower voltage coefficient of resistance and a lower head resistance.

Implementations in accordance with the disclosure are not limited to a particular orientation of the segments of the multi-segment resistors. For practical reasons, the long axes of the segments may be arranged about parallel to each other to simplify layout and increase space utilization efficiency. When arranged in this manner, the long axes may be oriented in any desired manner. In some cases it may be desirable to take into account the crystal orientation of the substrate 410. For example, it is known that silicon displays a piezo-resistive effect that depends on the orientation of the silicon crystal.

FIGS. 8A and 8B illustrate directions of carrier conduction in a (100) silicon wafer. Most conduction will occur along a crystal plane of the wafer, for example in <110> lattice directions as shown in FIG. 8A, and in <100> lattice directions as shown in FIG. 8B. (The <. . . > notation refers to a family of equivalent directions in the crystal lattice.) The conductivity in the <110> and <100> directions will in general respond differently to stress applied in the plane of the wafer. Table I below shows the piezo-resistive coefficients of current flow through the silicon wafer for the <110> and <100> directions. The longitudinal case (π_{L}) refers to stress applied parallel to the current flow direction and the transverse case (π_{T}) refers to stress applied perpendicular to the current flow direction. Note that for both the <110> and <100> directions, the effect of transverse stress (π_{T}) is less than the effect of longitudinal stress (π_{L}). Thus, while orientation of the multi-segment resistor is in principle unconstrained, it may be advantageous to ensure that when the device die is stressed, e.g. from a device package, the long axes of the resistor segments (the direction of current flow) are oriented normal to the stress.

TABLE I

| | <110> Directions | | <100> Directions | |
|---|---|---|---|---|
| | π_{L} (E⁻¹¹/Pa) | π_{T} (E⁻¹¹/Pa) | π_{L} (E⁻¹¹/Pa) | π_{T} (E⁻¹¹/Pa) |
| Electrons | −31.6 | −17.6 | −102 | 53.4 |
| Holes | 71.8 | −66.3 | 6.6 | −1.1 |

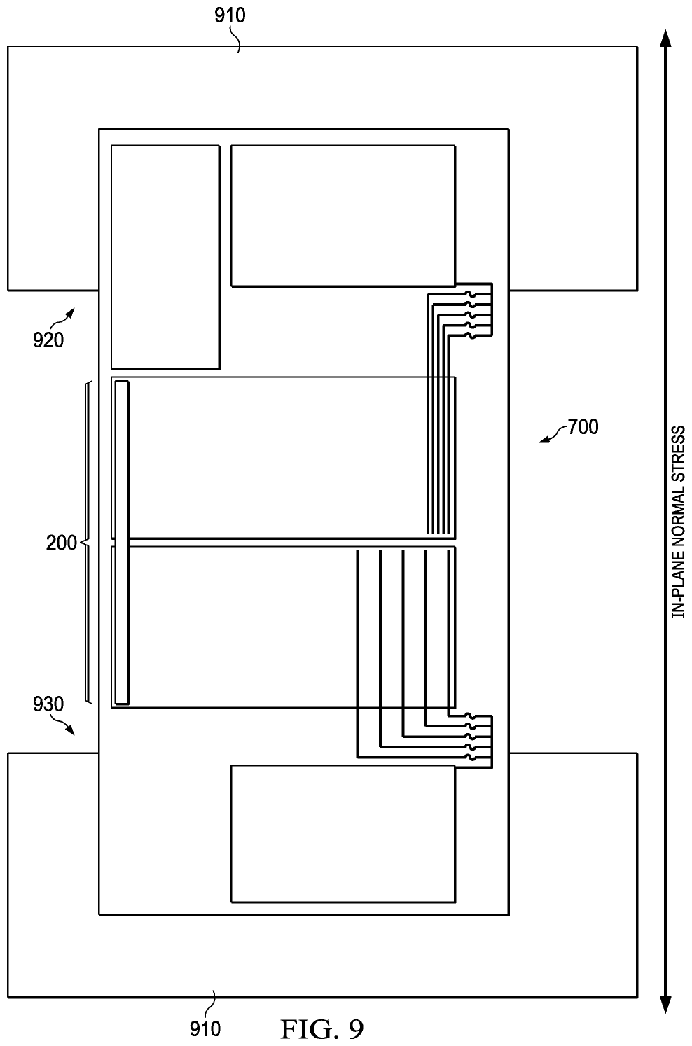

FIG. 9 shows in an illustrative example how the device 700 may be positioned on a package lead frame 910. First and second attachment ends 920, 930 of the device 700 define an attachment axis. The device 700 is typically bonded to the lead frame 910 via an adhesive, and a tensile stress in the lead frame 910 in the direction of the attachment axis may be transferred to the device 700 via the adhesive. A tensile (or compressive) stress on the device 700 die may result in the direction shown. It may therefore be preferable to have the current flow through the resistor segments arranged normal (transverse) to the stress vector to reduce the piezo-resistive effect on the resistance. This orientation results in the resistor segments being oriented with their long axes perpendicular to the attachment axis and the stress vector in the present example to reduce the effect of this stress.

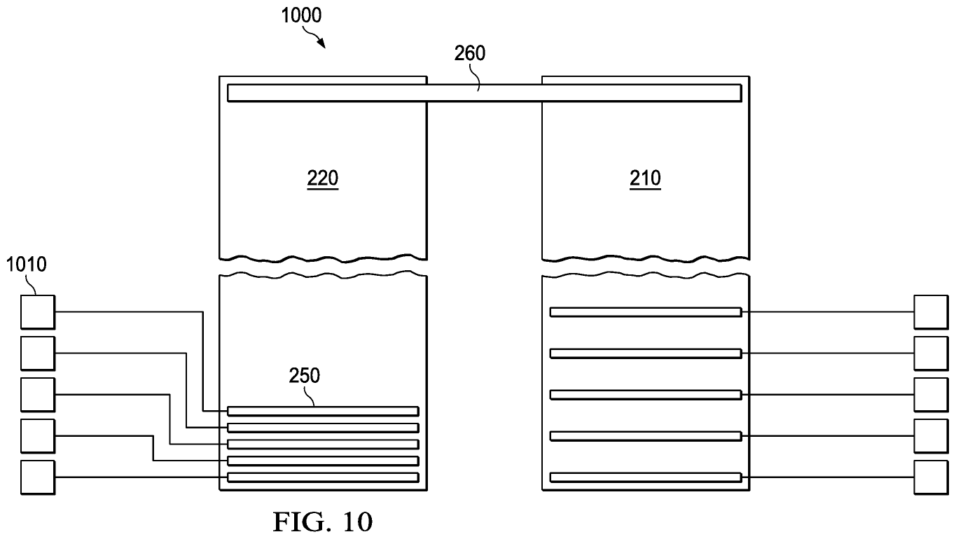

Turning now to FIG. 10, a first example is shown of a device 1000 having connections between the connection lines 250 of a two-body resistor and connection pads 1010. In this example each connection line 250 is connected to an individual connection pad 1010. The resistance of the device 1000 may be determined by selecting an appropriate one of the pads 1010 for a coarse adjustment, and selecting another appropriate one of the pads 1010 for a fine adjustment. Such selection may be made, e.g. by wire bonding from each of the selected pads 1010 to a corresponding package terminal.

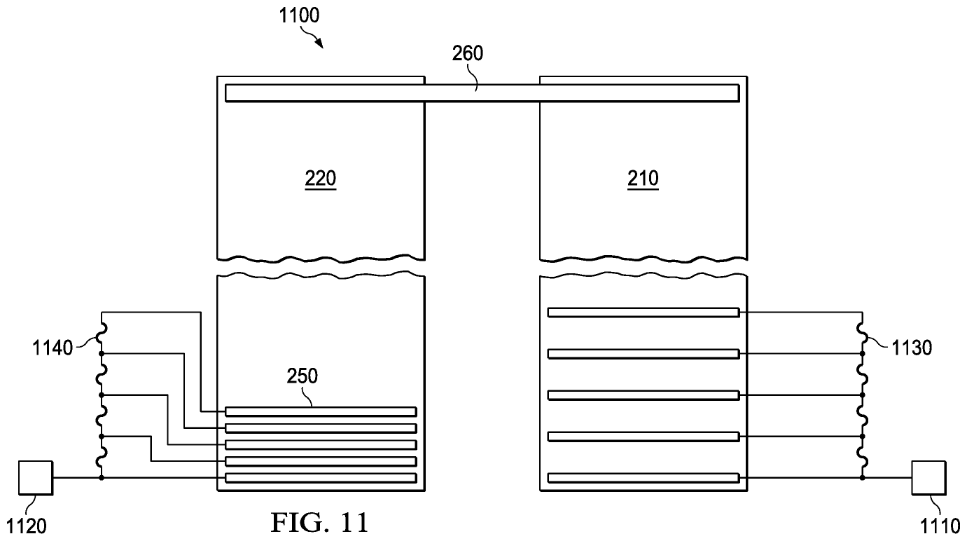

FIG. 11 illustrates a second example of a device 1100 having connections between the connection lines 250 of a two-body resistor and connection pads 1110, 1120. In this example each connection line 250 for coarse adjustment is initially connected to the connection pad 1110 either directly or through one or more fuses 1130 connected in series to the connection pad 1110. Each connection line 250 for fine adjustment is connected to the connection pad 1120 either directly or through one or more fuses 1140 connected in series to the connection pad 1120. The resistance of the device 1100 may be determined by blowing some, all or none of fuses 1130 for coarse adjustment, and blowing some, all or none of fuses 1140 for fine adjustment. The pads 1110 and 1120 may each then be wire bonded to corresponding terminals of a package terminal.

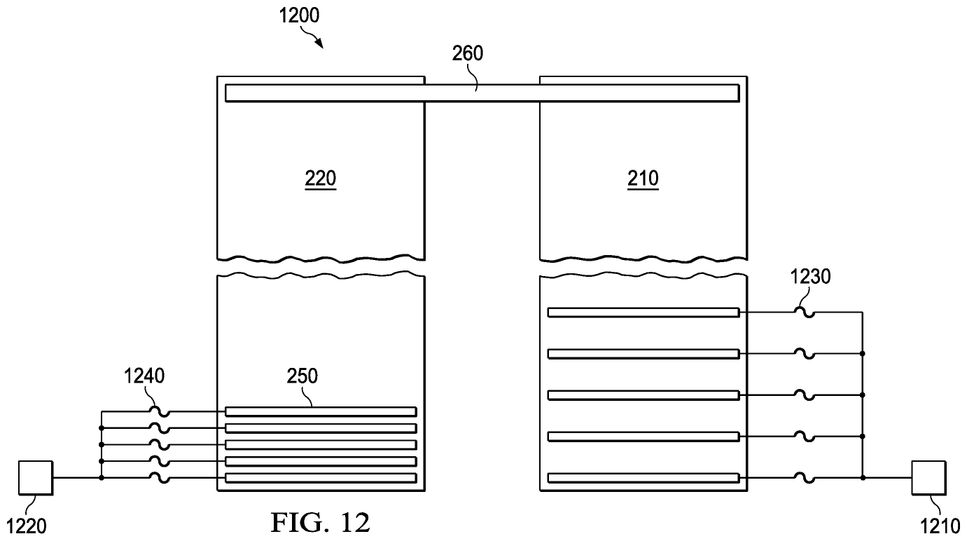

FIG. 12 illustrates a third example of a device 1200 having connections between the connection line 250 of a two-body resistor and connection pads 1210, 1220. In this example each connection line 250 for coarse adjustment is initially connected to the connection pad 1210 through one of fuses 1230 connected in parallel to the connection pad 1210. Each connection line 250 for fine adjustment is initially connected to the connection pad 1220 through one of fuses 1240 connected in parallel to the connection pad 1220. The resistance of the device 1200 may be determined by blowing some or none, but not all, of fuses 1230 for coarse adjustment, and blowing some or none, but not all, of fuses 1240 for fine adjustment. The pads 1210 and 1220 may each then be wire bonded to corresponding terminals of a package terminal.

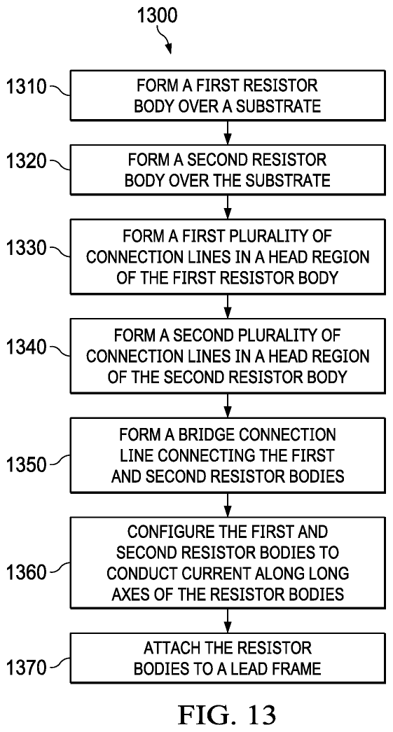

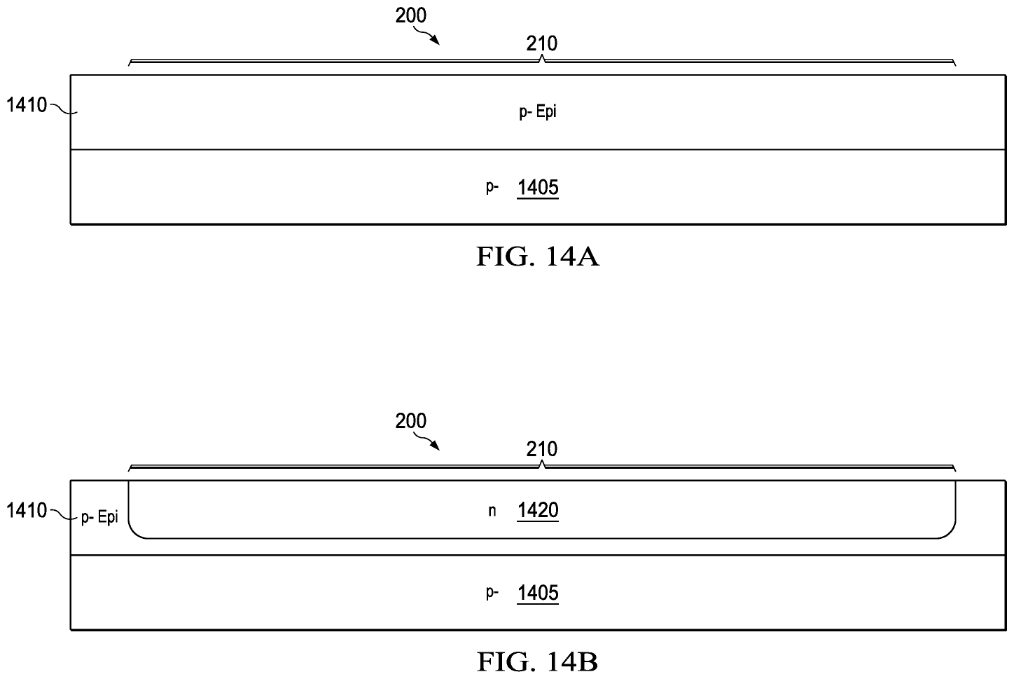

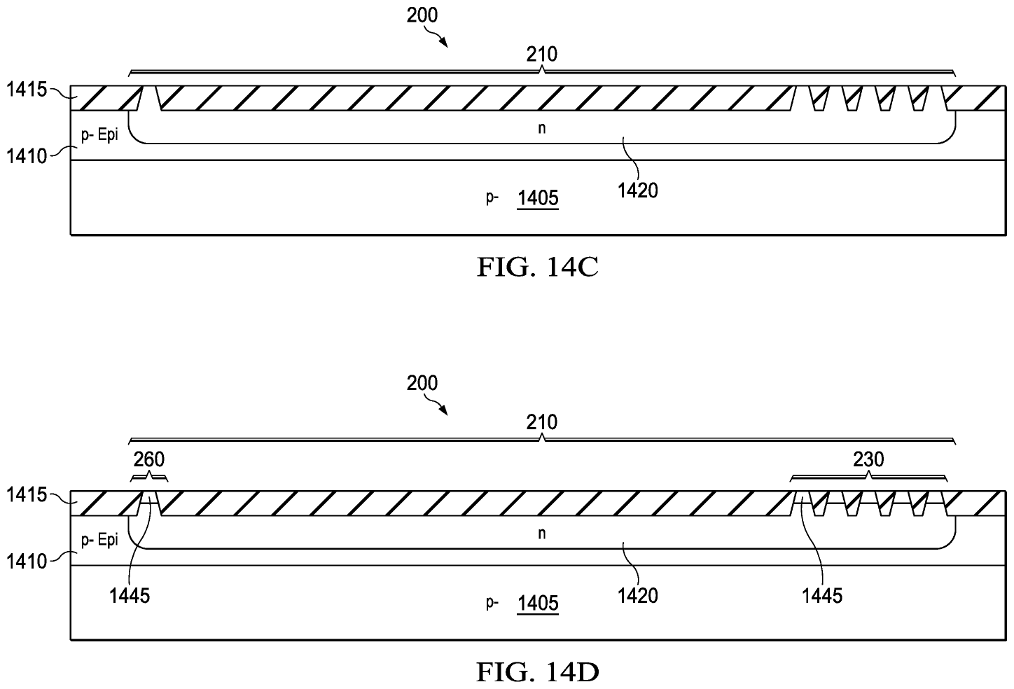

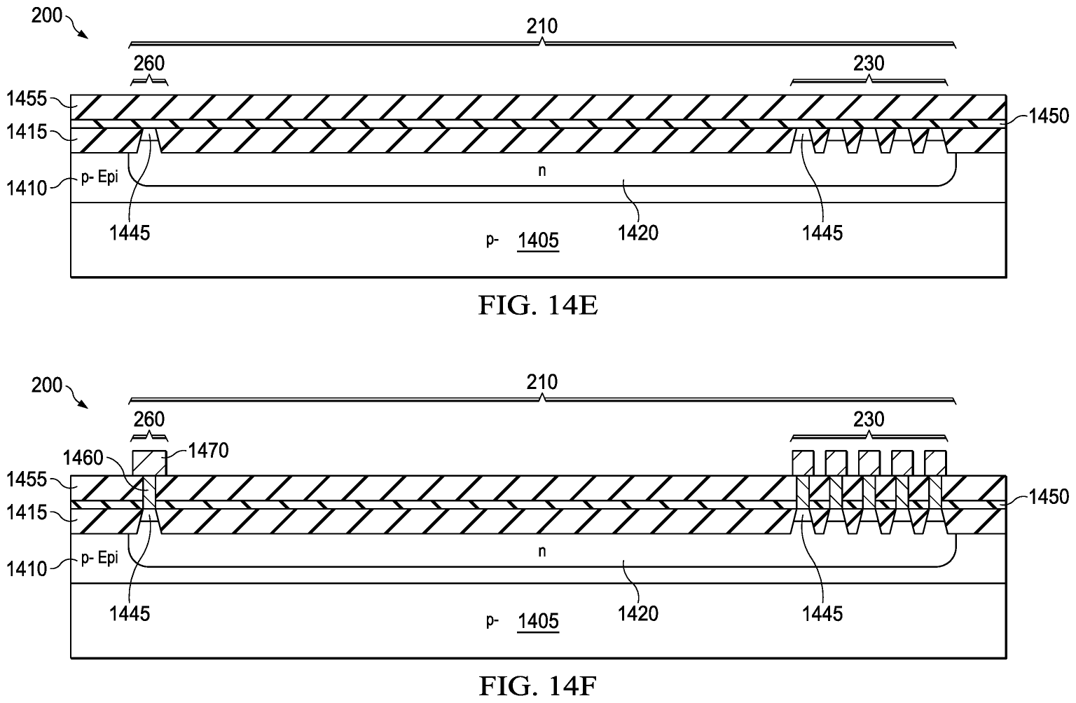

Turning to FIG. 13, an example method 1300 is shown for forming an electronic device according to the principles of the disclosure. The method 1300 is described with further reference to FIGS. 14A-14F, which show in one example progressive stages of manufacturing of a representative sectional view of the resistor segment 210, as indicated by the cutline shown in FIG. 3.

In a step 1310 a first resistor body is formed over a semiconductor substrate. The resistor body may be rectangular and have a long axis parallel to a longer dimension of the resistor body. Referring to FIG. 14A, a sectional view of the resistor segment 210 is shown at an early stage of formation. A lightly-doped p-type epitaxial layer 1410 has been formed over a lightly doped p-type substrate 1405. In FIG. 14B, an n-type well 1420 has been formed within the epitaxial layer 1410. The n-type well 1420 may be formed by conventional process steps including photolithography, n-type dopant implant, and anneal. In one example, the n-type well may be doped with phosphorous with a dose of about 1.7×10¹² cm⁻² with a junction depth of about 2.5 μm. In FIG. 14C, isolation regions 1415 have been formed, e.g. by an STI or LOCOS process.

Referring back to FIG. 13, in a step 1320 a second resistor body is formed over the substrate. The second resistor body may be formed as described for the first resistor body, and may be formed concurrently with the first resistor body. The second resistor body may also be rectangular, and have a long axis parallel to a longer dimension of the second resistor body. In various examples the long axes of the first and second resistor bodies are generally parallel to each other. The second resistor body may be one of several resistor bodies in addition to the first resistor body. In various examples all long axes of such resistor bodies are about parallel to each other.

In a step 1330 a first plurality of connection lines is formed in a head region of the first resistor body, and in a step 1340 a second plurality of connection lines is formed in a head region of the second resistor body. As described with respect to FIG. 1, the first plurality of connection lines may have a first spacing, and the second plurality of connection lines may have a second greater spacing. In a step 1350 a bridge connection is formed between the first and second resistor bodies. The bridge connection connects to ends of the resistor bodies opposite the head regions. The bridge connection may be a single conductive trace, e.g. a metal line, that connects the two resistor bodies. In some other examples the bridge connection may include any number of additional resistor bodies that are in turn connected to each other to form a chain of resistor bodies between first and second end resistor bodies, or end segments.

Referring to FIG. 14D, n+ contact strips 1445 have been formed, e.g. by n-type dopant implant into the exposed portions of the n-type well 1420. The contact strips 1445 may be regarded as connection terminals to the n-type well 1420. In a step not explicitly shown, the n+ contact strips may be silicided by a conventional process step. In FIG. 14E dielectric layers 1450 and 1455 have been formed over the substrate 1405. The dielectric layer 1450 may be present to maintain compatibility of the process sequence with a process flow used to form transistor gate dielectrics in other devices, and may optionally be omitted. The dielectric layers 1450 and 1455 may be silicon oxide or other suitable dielectric material. In FIG. 14F, metal interconnects, e.g. vias 1460 and lines 1470, have been formed. As shown, the metal interconnects may be formed by conventional tungsten plug and aluminum line processes. In other examples a copper damascene process may be used.

Referring again to FIG. 13, in a step 1360 the first and second resistor bodies are configured to conduct current along their long axes. Such configuration may include forming interconnections between the connection lines and contact pads, e.g. between the connection lines 250 and one pad 620 and between the connection lines 250 and another pad 620 (see FIG. 7). The connections may include fuses as previously described in any suitable configuration as exemplified by FIGS. 10-12. In a step 1370 a die on which the resistor bodies are formed is attached to a lead frame. The die may be attached such that stress imposed on the die is oriented about normal to the direction of current flow in the resistor bodies, for example as illustrated in FIG. 9. For example, the attachment points may be along an axis that is perpendicular to a direction of current flow in the resistor bodies.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. An electronic device, comprising:
first and a second rectangular resistor segment each having a doped resistive region formed in a semiconductor substrate, the first resistor segment having a first trim end and a first bridge end, and the second resistor segment having a second bridge end, the first and second bridge ends being adjacent;
a conductive line connected to the first bridge end and to the second bridge end; and
at least one connection terminal to the first resistor segment located at the first trim end.

2. The electronic device of claim 1, further comprising a third resistor segment, wherein the first and second resistor segments are end segments and the third resistor segment is an interior segment of a connected chain of segments.

3. The electronic device of claim 1, wherein the conductive line is a first conductive line and the second resistor segment is an interior resistor segment and is connected to a third resistor segment by a second conductive line.

4. The electronic device of claim 1, wherein the at least one connection terminal is one of a first plurality of connection terminals located at the first trim end, and further comprising a second plurality of connection terminals located at a second trim end of the second resistor segment, the first plurality of trim terminals having a first fill density, and the second plurality of trim terminals having a second greater fill density.

5. The electronic device of claim 2, wherein the at least one connection terminal is one of a first plurality of connection terminals located at the first trim end, and further comprising a second plurality of connection terminals located at a second trim end of the second resistor segment, the first plurality of trim terminals are spaced apart by about a same first distance, and the second plurality of trim terminals are spaced apart by about a same second distance that is greater than the first distance.

6. The electronic device of claim 1, wherein the at least one connection terminal spans substantially an entire width of the first resistive body.

7. The electronic device of claim 1, wherein the at least one connection terminal is one of a plurality of trim terminals, and further comprising a corresponding plurality of fuses, each fuse configured to sever a connection between one or more of the trim terminals a common connection terminal.

8. The electronic device of claim 1, wherein the first and second resistor segments are located on a device die attached to a lead frame, and long axes of the first and second resistor segments are oriented perpendicular to an attachment axis of the device die.

9. The electronic device of claim 1, wherein the first and second resistor segments are formed from respective first and second diffused n-type regions in a semiconductor substrate.

10. The electronic device of claim 1, wherein an aspect ratio of the first or second resistor body is no greater than about 2:1.

11. A method of forming an integrated circuit, comprising:
forming first and second rectangular resistor segments each having a doped resistive region formed in a semiconductor substrate, the first resistor segment having a first trim end and a first bridge end, and the second resistor segment having a second bridge end, the first and second bridge ends being adjacent;
forming an interconnect line connected to the first bridge end and to the second bridge end; and
forming at least one connection terminal to the doped resistive region located at the first trim end.

12. The method of claim 11, further comprising forming a third resistor segment, wherein the first and second resistor segments are end segments and the third resistor segment is an interior segment of a connected chain of segments.

13. The method of claim 11, wherein the interconnect line is a first interconnect line and the second resistor segment is an interior resistor segment and is connected to a third resistor segment by a second interconnect line.

14. The method of claim 11, wherein the at least one connection terminal is one of a first plurality of connection terminals located at the first trim end, and further comprising forming a second plurality of connection terminals located at a second trim end of the second resistor segment, the first plurality of trim terminals having a first fill density, and the second plurality of trim terminals having a second greater fill density.

15. The method of claim 12, wherein the at least one connection terminal is one of a first plurality of connection terminals located at the first trim end, and further comprising forming a second plurality of connection terminals located at a second trim end of the second resistor segment, the first plurality of trim terminals are spaced apart by about a same first distance, and the second plurality of trim terminals are spaced apart by about a same second distance that is greater than the first distance.

16. The method of claim 11, wherein the at least one connection terminal spans substantially an entire width of the first resistive body.

17. The method of claim 11, wherein the at least one connection terminal is one of a plurality of trim terminals, and further comprising forming a corresponding plurality of fuses, each fuse configurable to sever a connection between one or more of the trim terminals a common connection terminal.

18. The method of claim 11, wherein the first and second resistor segments are located on a device die attached to a lead frame, and long axes of the first and second resistor segments are oriented perpendicular to an attachment axis of the device die.

19. The method of claim 11, wherein the first and second resistor segments are formed from respective first and second diffused n-type regions in a semiconductor substrate.

20. The method of claim 11, wherein an aspect ratio of the first or second resistor body is no greater than about 2:1.
